(19) United States
(12) Patent Application Publication
(10) Pub. No.: US 2011/0253437 A1
(43) Pub. Date: Oct. 20, 2011

(54) PRINTED CIRCUIT BOARD AND PRINTED CIRCUIT BOARD ASSEMBLY

(75) Inventors: MEI HUANG, Shenzhen City (CN); LIANG GUO, Shenzhen City (CN); LI FAN, Shenzhen City (CN); HONG-LIAN HUANG, Shenzhen City (CN); JIAN LUO, Shenzhen City (CN); YI RUI, Shenzhen City (CN)

(73) Assignees: HON HAI PRECISION INDUSTRY CO., LTD., Tu-Cheng (TW); HON FU JIN PRECISION INDUSTRY (ShenZhen) CO., LTD., Shenzhen City (CN)

(21) Appl. No.: 12/823,279

(22) Filed: Jun. 25, 2010

(30) Foreign Application Priority Data
Apr. 16, 2010 (CN) 201010148812.2

(51) Int. Cl. H05K 1/18; H05K 1/00

(52) U.S. Cl. 174/260; 174/250

(57) ABSTRACT

A printed circuit board includes signal holes, at least one first securing hole, and at least one second securing hole. The signal holes and the first securing hole is able to secure a first electronic element or the signal holes and the second securing hole is able to secure a second electronic element.

### BACKGROUND

1. Technical Field

The present disclosure relates to printed circuit boards, especially to a printed circuit board and a printed circuit board assembly capable of securing two electronic devices having the same signal pins.

2. Description of Related Art

On a printed circuit board (PCB), areas for mounting electronic elements are designed for a specific element. And each mounting area includes several signal holes and several securing holes for securing an electronic element. This customization restricts the use of the motherboard and is an inconvenience. Therefore there is room for improvement in the art.

### BRIEF DESCRIPTION OF THE DRAWINGS

FIG. 1 is a schematic view of a printed circuit board of an embodiment.

FIG. 2 is an isometric view of a first display port connector of a printed circuit board of an embodiment.

FIG. 3 is an isometric view of a second display port connector of a printed circuit board of an embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

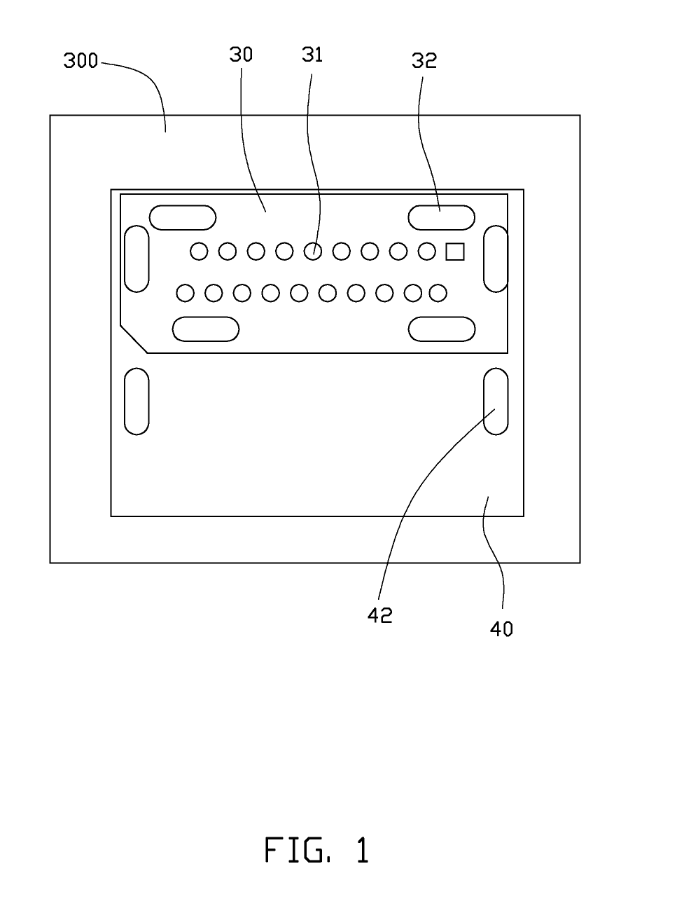

Referring to FIG. 1 a PCB 300 includes a first assembling area 30 and a second assembling area 40. The first assembling area 30 includes a plurality of signal connecting portions and a plurality of first securing portions. The second assembling area 40 includes the signal connecting portions and a plurality of second securing portions. In this embodiment, the signal connecting portions are signal holes 31, the first securing portions are elongated securing holes 32, and the second securing portions are elongated securing holes 42. The extending direction of the first elongated securing holes 32 is perpendicular to the extending direction of the second elongated securing holes 42. The signal holes 32 are aligned in two lines.

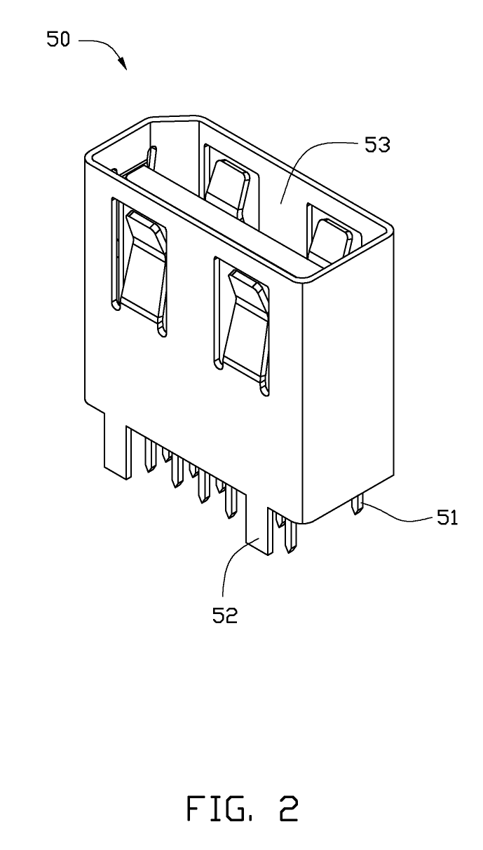

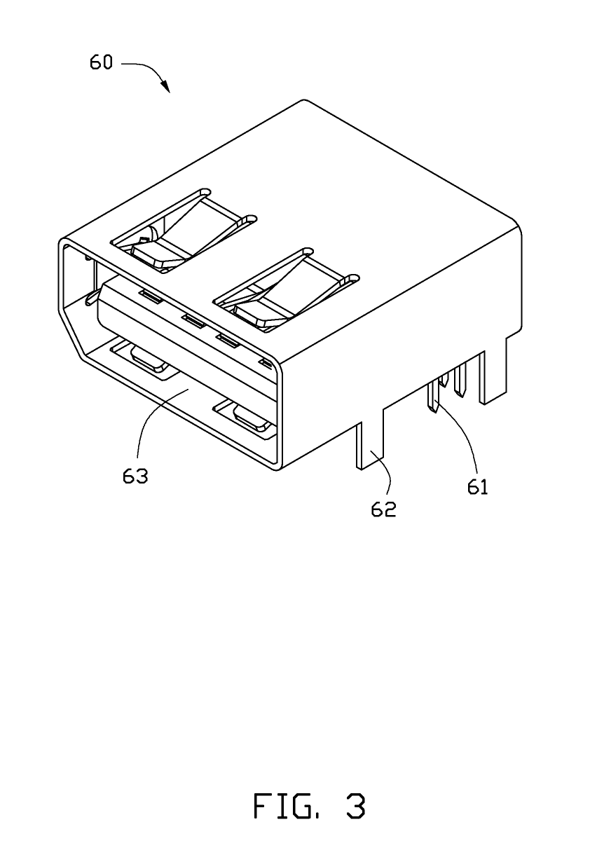

Also referring to FIGS. 2 and 3, a printed circuit board assembly of an embodiment may include an assembly of the PCB 300 and a first connector module, or an assembly of the PCB 300 and a second connector module.

The first connector module is a first display port connector 50. The first display port connector 50 includes a plurality of first signal pins 51 corresponding to the signal holes 31 of the PCB 300 and a plurality of first mounting portions. In one embodiment, the first mounting portion is a first securing pin 52. The first signal pins 51 are capable of being soldered in the corresponding signal holes 31. The first securing pins 52 are capable of being soldered in the corresponding first elongated securing holes 32. The first display port connector 50 defines a first opening 53 configured to receive a device. The receiving direction of the first opening 53 is parallel to the PCB 300.

The second display port connector 60 includes a plurality of second signal pins 61 corresponding to the signal holes 31 of the PCB 300 and a plurality of second mounting portions. In one embodiment, the second mounting portion is a second securing pin 62 corresponding to the second elongated securing hole 42. The second signal pins 61 are capable of being soldered in the signal holes 31. The second securing pins 62 are capable of being soldered in the second elongated securing holes 42. The second display port connector 60 defines a second opening 63 configured to receive a device. The receiving direction of the second opening 63 is perpendicular to the PCB 300.

The PCB 300 is capable of having either the first display port connector 50 or the second display port connector 60 coupled thereto, thus the PCB 300 is not restricted to connectors with one form factor.

It is to be understood, however, that even though numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A printed circuit board, comprising:
a plurality of signal holes;
at least one first securing hole; and
at least one second securing hole;
wherein the plurality of signal holes and the first securing hole are configured to commonly secure a first electronic element, and the plurality of signal holes and the second securing hole are configured to commonly secure a second electronic element.

2. The printed circuit board of claim 1, wherein the at least first securing hole and the at least second securing hole are elongated, an extending direction of the at least first securing hole is perpendicular to an extending direction of the at least second securing hole.

3. The printed circuit board of claim 1, wherein the at least first securing hole comprises two first securing holes, and the at least second securing hole comprises two second securing holes, wherein the two first securing holes are disposed at opposite sides of the plurality of the signal holes, and the two second securing holes are disposed at another opposite sides of the plurality of the signal holes.

4. The printed circuit board of claim 1, wherein the plurality of signal holes is aligned in two parallel lines.

5. A printed circuit board assembly, comprising:
a printed circuit board, the printed circuit board comprising:
a plurality of signal connecting portions;
a first securing portion;
a second securing portion; and
a first electronic element or a second electronic element;
wherein the plurality of signal connecting portions and the first securing portion are configured to commonly secure the first electronic element, and the plurality of signal connecting portions and the second securing portion are configured to commonly secure the second electronic element.

6. The printed circuit board assembly of claim 5, wherein the first electronic element comprises a plurality of first signal pins corresponding to the plurality of the signal connecting portions and a first securing pin corresponding to the first securing portion, and the second electronic element comprises a plurality of second signal pins corresponding to the plurality of the signal connecting portions and a second securing pin corresponding to the second securing portion.

7. The printed circuit board assembly of claim 5, wherein the signal connecting portion is a signal hole.

8. The printed circuit board assembly of claim 7, wherein the plurality of signal holes is aligned in two lines.

9. The printed circuit board assembly of claim 5, wherein the first securing portion is a first securing hole.

10. The printed circuit board assembly of claim 9, wherein the second securing portion is a second securing hole.

11. The printed circuit board assembly of claim 10, wherein the first securing hole and the second securing hole are elongated, an extending direction of the first securing hole is perpendicular to an extending direction of the second securing hole.

12. The printed circuit board assembly of claim 5, wherein the first electronic device is a display port connector, the display port connector defines an opening configured to receive a device, a receiving direction of the opening is perpendicular to the printed circuit board.

13. The printed circuit board assembly of claim 5, wherein the second electronic device is a display port connector, the display port connector defines an opening configured to receive a device, a receiving direction of the opening is parallel to the printed circuit board.

14. A printed circuit board assembly, comprising:
a printed circuit board, the printed circuit board comprising:
a plurality of signal holes;
two first securing holes;
two second securing holes; and
a first electronic element or a second electronic element;
wherein the plurality of signal holes and the two first securing holes are configured to commonly secure the first electronic element, and the plurality of signal holes and the two second securing holes are configured to commonly secure the second electronic element; the two first securing holes are disposed at opposite sides of the plurality of the signal holes, and the two second securing holes are disposed at another opposite sides of the sides of the plurality of the signal holes.

15. The printed circuit board assembly of claim 14, wherein the first electronic element comprises a plurality of first signal pins corresponding to the plurality of the signal holes and two first securing pins corresponding to the two first securing holes, and the second electronic element comprises a plurality of second signal pins corresponding to the plurality of the signal holes and two second securing pins corresponding to the two second securing holes.

16. The printed circuit board assembly of claim 14, wherein the two first securing holes and the two first securing holes are elongated, and an extending direction of the first securing hole is perpendicular to an extending direction of the second securing hole.

17. The printed circuit board assembly of claim 12, wherein the first electronic device is a display port connector, the display port connector defines an opening configured to receive a device, a receiving direction of the opening is perpendicular to the printed circuit board.

18. The printed circuit board assembly of claim 12, wherein the second electronic device is a display port connector, the display port connector defines an opening configured to receive a device, a receiving direction of the opening is parallel to the printed circuit board.
